(19) United States
(12) Patent Application Publication
(10) Pub. No.: US 2024/0102163 A1
(43) Pub. Date: Mar. 28, 2024

(54) COMPOSITIONS COMPRISING BORAZINE AND ITS DERIVATIVES, AND RELATED METHODS AND SYSTEMS

(71) Applicant: ASM IP Holding, B.V., Almere (NL)

(72) Inventors: Patricio Romero, Wilsele (BE); Charles Dezelah, Helsinki (FI); Viljami J. Pore, Helsinki (FI)

(21) Appl. No.: 18/463,034

(22) Filed: Sep. 7, 2023

Related U.S. Application Data
(60) Provisional application No. 63/375,084, filed on Sep. 9, 2022.

(51) Int. Cl. C23C 16/455

(52) U.S. Cl. CPC C23C 16/45553

(57) ABSTRACT

Compositions, related methods, and related systems are disclosed. The compositions can comprise a precursor and a liquid solvent. The precursor can be unstable in substantially pure form in an inert atmosphere at a temperature of at least 10° C. to at most 100° C. The solvent can have a vapor pressure of at most 1.0 mPa at a temperature of 20° C.

### CROSS-REFERENCE TO RELATED APPLICATION(S)

This application claims the benefit of U.S. Provisional Application 63/375,084 filed on Sep. 9, 2022, the entire contents of which are incorporated herein by reference.

### FIELD OF INVENTION

The present disclosure generally relates to compositions for precursor delivery, to related methods, and to related systems. The compositions can be particularly useful for stabilizing precursors, thereby extending their shelf life compared to that of the precursors in substantially pure form.

### BACKGROUND OF THE DISCLOSURE

Precursors are used in the semiconductor industry for forming material layers using a variety of techniques such as chemical vapor deposition (CVD), atomic layer deposition (ALD), plasma-enhanced chemical vapor deposition (PE-CVD), and plasma-enhanced atomic layer deposition (PE-ALD). The material properties are strongly influenced by the particular precursors used. In some cases, precursors that can be used to form layers having excellent properties unfortunately suffer from poor shelf life. Thus, there is a need for ways to increase the shelf life of precursors.

Any discussion of problems and solutions set forth in this section has been included in this disclosure solely for the purposes of providing a context for the present disclosure, and should not be taken as an admission that any or all of the discussion was known at the time the invention was made.

### SUMMARY OF THE DISCLOSURE

Exemplary embodiments of this disclosure relate to compositions comprising a solvent and a precursor, to related methods, and to related systems. While the ways in which various embodiments of the present disclosure address drawbacks of prior methods are discussed in more detail below, in general, various embodiments of the disclosure provide methods that can be used to improve the stability of borazine and its derivatives.

Particularly described herein is a composition that comprises a precursor and a liquid solvent. The precursor undergoes at least one of self-condensation and polymerization in substantially pure form in an inert atmosphere at a temperature of at least 10° C. to at most 100° C. The solvent has a vapor pressure of at most 1.0 mPa at a temperature of 20° C.

In some embodiments, the solvent comprises an ionic liquid.

In some embodiments, the ionic liquid comprises a cation selected from

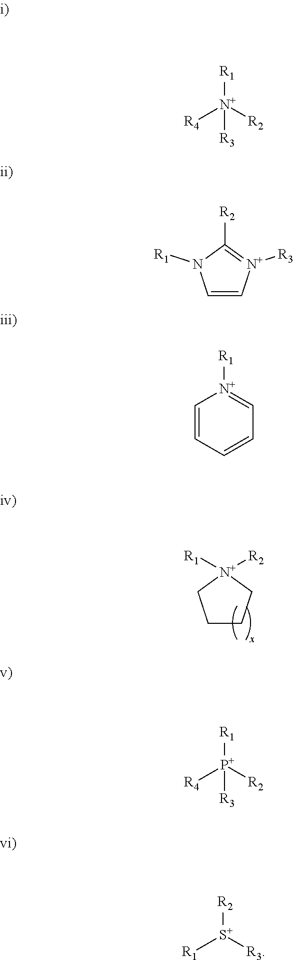

It shall be understood that x is 0 or 1, and that R1, R2, R3, and R4 are independently selected from a hydrocarbyl.

In some embodiments, the ionic liquid comprises an anion selected from CF₃CO₂⁻, N(CN)₂⁻, C(CN₃)₃⁻, SeCN⁻, CuCl₂, AlCl₄, and ZnCl₄²⁻.

In some embodiments, the ionic liquid comprises an anion, and the anion is selected from a boron-containing anion, a phosphorous-containing anion, and a sulphur-containing anion.

In some embodiments, the composition comprises a boron-containing anion, and the boron-containing anion is selected from the list consisting of BF₄, B(CN₄)⁻, CH₃BF₃⁻, CH₂CHBF₃⁻, CF₃BF₃⁻, C₂F₅BF₃⁻, n-C₃F₇BF₃⁻, and n-C₄F₉BF₃⁻.

In some embodiments, the composition comprises an anion that contains phosphorous such as PF₆⁻ or (C₂F₅)₃PF₃⁻.

In some embodiments, the composition comprises a sulphur-containing anion. The sulphur-containing anion is selected from the list consisting of CF₃SO₃⁻, N(SO₂CF₃)₂⁻, N(COCF₃)(SO₂CF₃)⁻, N(SO₂F)₂⁻, ROSO₃⁻, and SCN⁻, wherein R is a C1 to C20 hydrocarbyl.

In some embodiments, the ionic liquid has a formula according to formula a)

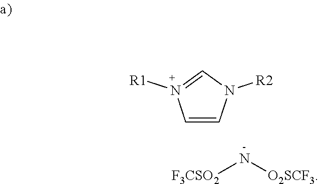

It shall be understood that R1 and R2 are hydrocarbyls.

In some embodiments, R1 and R2 are alkyls.

In some embodiments, R1 is methyl and R2 is ethyl.

In some embodiments, the solvent comprises a liquid polymer.

In some embodiments, the liquid polymer is a polyether.

In some embodiments, the precursor comprises one or more of a cyclic silane, a solid precursor, and a heterocyclic compound.

In some embodiments, the precursor comprises the heterocyclic compound, and the heterocyclic compound comprises one or more bonds selected from a boron-nitrogen bond, a carbon-nitrogen bond, a silicon-carbon bond, and a nitrogen-silicon bond.

In some embodiments, the heterocyclic precursor further comprises a silicon-silicon bond.

In some embodiments, the heterocyclic compound is borazine or a borazine derivative.

Further described herein is a method of storing a precursor in a precursor vessel. The method comprises providing a precursor vessel. The precursor vessel comprises a composition as described herein. The method further comprises maintaining the composition at a temperature of at least 10° C. to at most 50° C. for a duration of at least one week to at most one year.

Further described herein is a system that comprises a reaction chamber, a substrate handling system, a precursor source, and a controller. The precursor source comprises a composition as described herein. The controller is arranged for causing the system to provide a vapor to the reaction chamber. The vapor comprising the precursor that is comprised in the composition.

Further described herein is a precursor vessel that comprises a container and a composition as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 shows how borazine can be dissolved in an ionic liquid to form a composition according to an embodiment of the present disclosure.

FIG. 2 shows an embodiment of a reactor according to the present disclosure.

FIG. 3 illustrates a system (300) in accordance with an embodiment of the disclosure.

FIG. 4 shows an embodiment of a precursor vessel (400) that comprises a composition (420) as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses described herein and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibres or polymer fibres). Continuous substrates may also comprise carriers or sheets upon which non-continuous substrates are mounted.

In some embodiments, the terms “film” and “layer” may be used interchangeably and refer to a layer extending in a direction perpendicular to a thickness direction to cover an entire target or concerned surface, or simply a layer covering a target or concerned surface. In some embodiments, the terms “film” or “layer” refer to a structure having a certain thickness formed on a surface. A film or layer may be constituted by a discrete single film or layer having certain characteristics. Alternatively, a film or layer may be constituted of multiple films or layers, and a boundary between adjacent films or layers may or may not be clear and may or may not be established based on physical, chemical, and/or any other characteristics, formation processes or sequence, and/or functions or purposes of the adjacent films or layers.

In some embodiments, “gas” can include material that is a gas at normal temperature and pressure, a vaporized solid and/or a vaporized liquid, and may be constituted by a single gas or a mixture of gases, depending on the context. A gas can include a process gas or other gas that passes through a gas supply unit, such as a shower plate, a gas distribution device, or the like. A gas can be a reactant or precursor that takes part in a reaction within a reaction chamber and/or include ambient gas, such as air.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments. Percentages set forth herein are absolute percentages, unless otherwise noted.

It shall be understood that the term “comprising” is open ended and does not exclude the presence of other elements or components, unless the context clearly indicates otherwise. The term “comprising” includes the meaning of “consisting of.” The term “consisting of” indicates that no other features or components are present than those mentioned, unless the context indicates otherwise.

It shall be understood that Et stands for ethyl.

“Inert atmosphere” can refer to an atmosphere that does not, or does not substantially, react with the precursor in question. Suitable inert atmospheres include atmospheres that consist, or substantially consist of, a noble gas such as He, Ne, Ar, Xe, or Kr.

Described herein is a composition. Also described herein is a precursor vessel that comprises a composition as described herein.

The composition comprises a precursor and a solvent. The solvent can be a liquid. It shall be understood that the term “liquid” as used herein includes liquid-like substance such as non-Newtonian fluids, such as a Bingham plastics. The solvent can be in the liquid state at room temperature and atmospheric pressure.

In some embodiments, the precursor is, in pure form or in substantially pure form, prone to self-condensation, polymerization, or any other similar process that is driven by short-range intermolecular interactions. In particular, the precursor can be prone to such processes when the precursor is kept in pure form, or in substantially pure form, in an inert atmosphere and at a temperature of at least at least 10° C. to at most 100° C. In some embodiments, a precursor that is prone to self-condensation, polymerization, or any other similar process that is driven by short-range intermolecular interactions can be referred to as an unstable precursor.

In some embodiments, “pure form” or “substantially pure form” refers to a precursor purity of at least 98 atomic percent, or of at least 99 atomic percent, or of at least 99.9 atomic percent, or of at least 99.99 atomic percent, or of at least 99.999 atomic percent, or of at least 99.9999 atomic percent.

In some embodiments, the occurrence of self-condensation or polymerization can be measured using a viscosity measurement. Viscosity measurements per se are known in the art and include rotational rheometry, a vibrating viscometer, or a microfluidic rheometer. For example, a 1, 2, 5, 10, or 20 percent increase in viscosity over a time period of 1, 2, 3, 6, or 12 months can be considered to be a marker of self-condensation or polymerization.

In some embodiments, the precursor is unstable in substantially pure form when it is kept in an inert atmosphere and at a temperature of at least 10° C. to at most 100° C.

In some embodiments, the precursor is a solid at atmospheric pressure and at a temperature of at least 10° C. to at most 100° C.

In some embodiments, the precursor comprises one or more of a cyclic silane, a solid precursor, and a heterocyclic compound.

In some embodiments, the precursor comprises a silane. Suitable silanes include cyclic silanes such as cyclohexasilane.

In some embodiments, the precursor comprises a heterocyclic compound. The heterocyclic compound can comprise one or more bonds selected from a boron-nitrogen bond, a carbon-nitrogen bond, a silicon-carbon bond, and a nitrogen-silicon bond.

In some embodiments, the heterocyclic precursor further comprises a silicon-silicon bond.

In some embodiments, the heterocyclic compound is borazine or a borazine derivative. Suitable borazine derivatives include borazine halides such as borazine chlorides, borazine bromides, and borazine iodides. For example, the precursor can comprise 2,4,6-trichloroborazine.

In some embodiments, the precursor consists of boron, nitrogen, and hydrogen. In some embodiments, the precursor can be represented by a chemical formula according to formula (a)

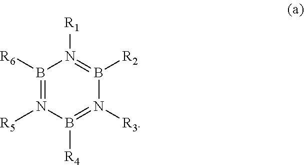

It shall be understood that R₁, R₂, R₃, R₄, R₅, and R₆ can be independently selected from H and a halogen. In some embodiments, at least one of R₁, R₂, R₃, R₄, R₅, and R₆ is F or Cl. Alternatively, R₁, R₂, R₃, R₄, R₅, and R₆ may all be H. In some embodiments, R₁, R₃, and R₅ are a halogen such as Cl, and R₂, R₄, and R₆ are H. Accordingly, in some embodiments, the precursor is borazine. In some embodiments, the precursor is a substituted borazine. In some embodiments, the precursor does not comprise carbon. In accordance with further examples, one or more halogen substituents may be selected from the group consisting of F, Cl, Br, and I.

In some embodiments, the precursor is a solid in substantially pure form at room temperature and at atmospheric pressure. Exemplary solid precursors include metal halides, such as transition metal halides such as HfCl₄, ZrCl₄, and NbCl₅. Further exemplary solid precursors include post transition metal halides such as AlCl₃. Further exemplary solid precursors include metal carbonyls, such as transition metal carbonyls, such as Mo(CO)₆.

In some embodiments, the solvent has a vapor pressure of at most 1.0 mPa at a temperature of 20° C. In some embodiments, the solvent has a vapor pressure of at most 1.0 μPa at a temperature of 20° C. In some embodiments, the solvent has a vapor pressure of at most 10 μPa at a temperature of 20° C. In some embodiments, the solvent has a vapor pressure of at most 100 μPa at a temperature of 20° C.

In some embodiments, vapor pressure can be measured by Thermogravimetric Analysis (TGA). The evaporation rate of a chemical compound can be correlated to vapor pressure and can be fitted to a calibration curve. The vapor pressure of solvents such as ionic liquids which can be used in the presently described compositions, methods, and systems is detectable, but very low. Thermogravimetric Analysis for vapor pressure measurement is described in Green Chemistry, 2009, 11, 1217-1221.

In some embodiments, the vapor pressure of the solvent is at least 10³, 10⁴, 10⁵, 10⁶, 10⁷, 10⁸, 10⁹, 10¹⁰, 10¹¹, or 10¹² times lower than the vapor pressure of the precursor. It shall be understood that in such embodiments, the respective vapor pressures are determined under the conditions, i.e. pressure, temperature, and concentration, under which the presently disclosed condition is kept.

In some embodiments, a composition as described herein has a precursor concentration which is below the critical concentration above which thermal polymerization or self-condensation occurs. For example, a composition as described herein can have a precursor concentration of at least 1 mole percent to at most 2 mole percent, or a precursor concentration of at least 2 mole percent to at most 5 mole percent, or a precursor concentration of at least 5 mole percent to at most 10 mole percent, or a precursor concentration of at least 10 mole percent to at most 20 mole percent, or a precursor concentration of at least 20 mole percent to at most 50 mole percent, or a precursor concentration of at least 50 mole percent to at most 70 mole percent.

In some embodiments, the solvent comprises an ionic liquid. It shall be understood that the term “ionic liquid” as used herein refers to a salt that exists in the liquid state at 25° C. and at a pressure of 1 atm.

Suitable ionic liquids comprise a cation and an anion. The ionic liquid can comprise any suitable anion. The ionic liquid can comprise any suitable cation. In some embodiments, the ionic liquid comprises a cation selected from

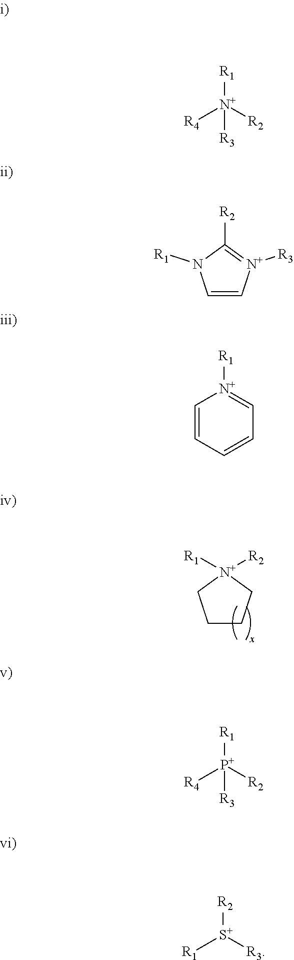

It shall be understood that in a compound according to formula iv, x is 0 or 1. In some embodiments of the compounds according to formulas i through vi, R1, R2, R3, and R4 are independently selected from a hydrocarbyl. In some embodiments, R1, R2, R3, and R4 can be independently selected. They can be the same or they can be different. In some embodiments, at least one of R1, R2, R3, and R4 is an alkyl. In some embodiments, at least one of R1, R2, R3, and R4 is methyl. In some embodiments, at least one of R1, R2, R3, and R4 is ethyl. In some embodiments, at least one of R1, R2, R3, and R4 is H.

In some embodiments, the ionic liquid comprises an anion selected from CF₃CO₂⁻, N(CN)₂⁻, C(CN₃)₃⁻, SeCN⁻, CuCl₂, AlCl₄, and ZnCl₄²⁻.

In some embodiments, the anion is selected from a boron-containing anion, a phosphorous-containing anion, and a sulphur-containing anion. In some embodiments, the anion comprises a boron-containing anion. In some embodiments, the anion comprises a phosphorous-containing anion. In some embodiments, the anion comprises a sulphur-containing anion.

In some embodiments, the boron-containing anion is selected from the list consisting of BF₄, B(CN₄)⁻, CH₃BF₃⁻, CH₂CHBF₃⁻, CF₃BF₃⁻, C₂F₅BF₃⁻, n-C₃F₇BF₃⁻, and n-C₄F₉BF₃⁻.

In some embodiments, the phosphorous-containing anion is selected from PF₆⁻ and (C₂F₅)₃PF₃⁻.

In some embodiments, the sulphur-containing anion is selected from the list consisting of CF₃SO₃⁻, N(SO₂CF₃)₂⁻, N(COCF₃)(SO₂CF₃)⁻, N(SO₂F)₂⁻, ROSO₃⁻, and SCN⁻, wherein R is a C1 to C20 hydrocarbyl. For example, R can be selected from methyl, ethyl, propyl, butyl, pentyl, and hexyl. In some embodiments, R is ethyl.

In some embodiments, the ionic liquid has a formula according to formula a)

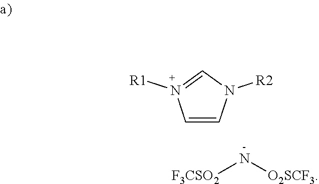

It shall be understood that R1 and R2 are hydrocarbyls. R1 and R2 may be identical, or they may be different. In some embodiments, R1 and R2 are alkyls. In some embodiments, R1 is methyl and R2 is ethyl.

In some embodiments, the solvent comprises a liquid polymer. In some embodiments, the solvent comprises a liquid oligomer. It shall be understood that a liquid polymer can refer to a polymer which is a liquid, or a non-Newtonian fluid, at a temperature of 20° C. and at atmospheric pressure. Similarly, a liquid oligomer can refer to a polymer which is a liquid, or a non-Newtonian fluid, at a temperature of 20° C. and at atmospheric pressure.

It shall be understood that “oligomer” can refer to a compound that comprises from at least 2 to at most 100 repeating units. The term “polymer” can refer to a compound that comprises more than 100 repeating units. Oligomers and polymers can be linear, branched, or cyclic.

Suitable liquid polymers and oligomers include polyethers. Suitable polyethers include polyethylene glycol and polypropylene glycol.

Further described herein is a method of storing a precursor in a precursor vessel. The method comprises providing a precursor vessel that comprises a composition as described herein. The composition is maintained at a temperature of at least 10° C. to at most 100° C. for a duration of at least one week to at most one year.

In some embodiments, the composition is maintained at a temperature of at least 20° C. to at most 50° C., or at a temperature of at least 10° C. to at most 50° C., or at a temperature of at least 50° C. to at most 100° C.

In some temperature, the composition is maintained at an aforementioned temperature for a duration of at least 1 week to at most 2 weeks, or for at least 2 weeks to at most 5 weeks, or for at least 5 weeks to at most 10 weeks, or for at least 10 weeks to at most 20 weeks, or for at least 20 weeks to at most 1 year.

Further described herein is a system that comprises a reaction chamber, a substrate handling system, a precursor source, and a controller. The precursor source comprises a composition as described herein. Th controller is arranged for causing the system to provide a vapor to the reaction chamber. The vapor comprises the precursor that is comprised in the presently described composition.

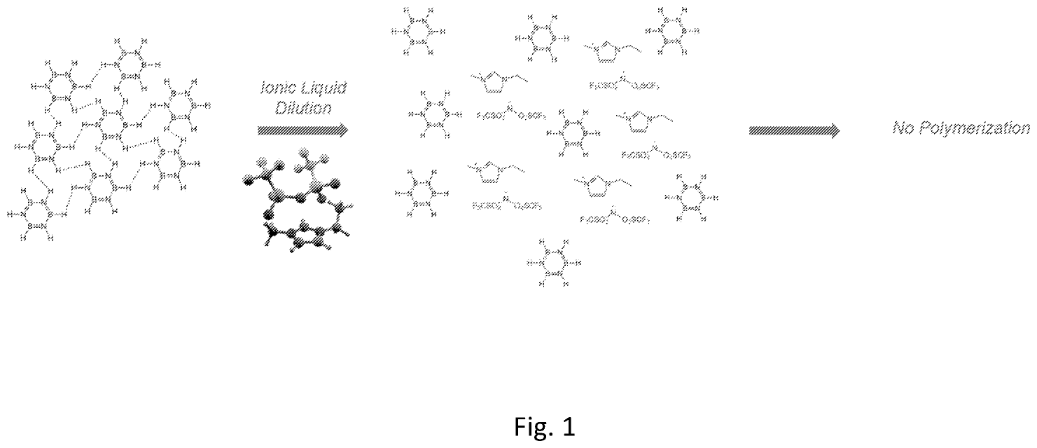

In an exemplary embodiment, reference is made to FIG. 1. FIG. 1 shows how borazine can be dissolved in an ionic liquid to form a composition according to an embodiment of the present disclosure. A reduction in interaction between borazine molecules reduces in a reduction of the polymerization rate, or even in an inhibition of borazine polymerization. The ionic liquid particularly has a formula given by formula a)

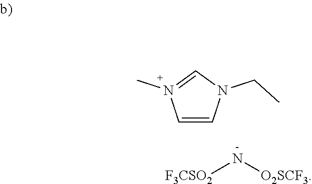

The presently disclosed compositions can strongly increase the shelf life of borazine in a precursor vessel, e.g. an uncooled precursor vessel at room temperature, compared to neat, i.e. undissolved, borazine. Indeed, neat borazine polymerizes at room temperature. Polymerization is a process that combines many small molecules (monomers) into a covalently bonded chain. Neat Borazine, with a nominal concentration of 10.06 mol/L, undergoes self-polymerization at or above room temperature with accompanied by H₂ generation (dehydrocoupling). Decreasing the monomer concentration in a given solvent, leads to much slower kinetics and retardation of the polymerization process, or stopping it altogether. Ultra low vapor pressure solvents as dilution agents to discourage inter-molecular interactions and avoid the undesired polymerization.

Using a low vapor pressure solvent as disclosed herein allows generating a substantially pure borazine gas stream, comprising a low or negligible solvent concentration. Such a substantially pure borazine stream can be used for forming a layer, such as a boron nitride-containing layer, on a substrate. For example, an ionic liquid can be used. Any ionic liquid of adequate viscosity and with a melting point below room temperature, may be suitable for this application. Given their very low to negligible vapor pressure, ionic liquids would not contribute to the vapor flux and act only as a dilution agent, thereby stabilizing the borazine precursor and allowing the corresponding ionic liquid—borazine mixture to act as a source of essentially pure borazine vapor, with little to no solvent contamination.

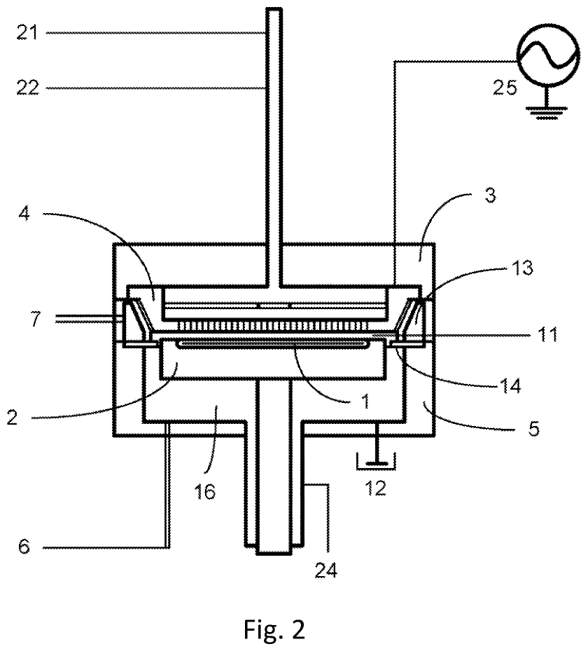

The presently disclosed compositions may be used as a precursor source for any suitable apparatus, including in a reactor as shown in FIG. 2, which can be particularly used to form a layer on a substrate using a composition as described herein. In this figure, by providing a pair of electrically conductive flat-plate electrodes (2,4) in parallel and facing each other in the interior (11) (reaction zone) of a reaction chamber (3), applying RF power (e.g. at 13.56 MHz and/or 27 MHz) from a power source (25) to one side, and electrically grounding the other side (12), a plasma is excited between the electrodes. A temperature regulator may be provided in a lower stage (2), i.e. the lower electrode. A substrate (1) is placed thereon and its temperature is kept constant at a given temperature. The upper electrode (4) can serve as a shower plate as well, and a reactant gas and/or a dilution gas, if any, as well as a precursor gas can be introduced into the reaction chamber (3) through a gas line (21) and a gas line (22), respectively, and through the shower plate (4). Additionally, in the reaction chamber (3), a circular duct (13) with an exhaust line (17) is provided, through which the gas in the interior (11) of the reaction chamber (3) is exhausted. Additionally, a transfer chamber (5) is disposed below the reaction chamber (3) and is provided with a gas seal line (24) to introduce seal gas into the interior (11) of the reaction chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6). A skilled artisan will appreciate that the apparatus includes one or more controller(s) (not shown) programmed or otherwise configured to cause a deposition process described to be conducted. The controller(s) communicate with the various power sources, heating systems, pumps, robotics and gas flow controllers or valves of the reactor, as will be appreciated by the skilled artisan. The controller(s) include electronic circuitry including a processor, and software to selectively operate valves, manifolds, heaters, pumps and other components included in the system. Such circuitry and components operate to introduce precursors, reactants, and optionally purge gases from the respective sources such as the precursor vessel (20). The precursor vessel (20) comprises a composition as described herein. The controller can control timing of gas supply sequences, temperature of the substrate and/or reaction chamber (3), pressure within the reaction chamber (3), and various other operations to provide proper operation of the system. The controller(s) can include control software to electrically or pneumatically control valves to control flow of precursors, reactants and purge gases into and out of the reaction chamber (3). Controller(s) can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e. memory, of the control system and be configured to execute one or more processes.

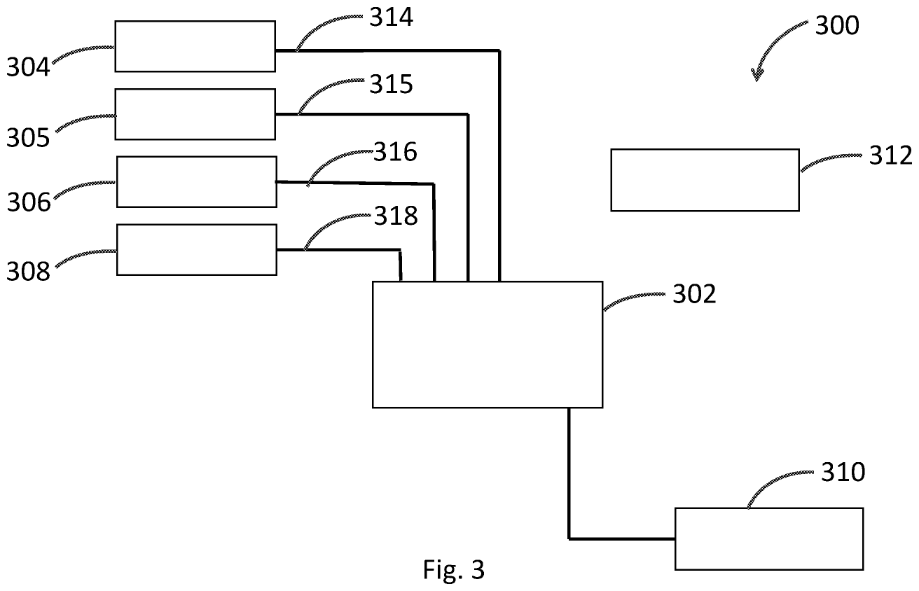

FIG. 3 illustrates a system (300) in accordance with exemplary embodiments of the disclosure. The system (300) can be configured to perform a method as described herein using a composition as disclosed herein. In the illustrated example, the system (300) includes one or more reaction chambers (302), a first precursor gas source (304), a second precursor gas source (306), a reactant gas source (308), an exhaust (310), and a controller (312). In some embodiments, the system further comprises a second precursor gas source (not shown). The reaction chamber (302) can include an ALD reaction chamber.

The first precursor gas source (304) can include a vessel and a composition as disclosed herein. The second precursor gas source (306) can include a vessel and a precursor, alone, in a composition as disclosed herein, or mixed with one or more carrier gases. The reactant gas source (308) can include one or more reactants such as oxygen, ammonia, water, or the like.

Although illustrated with four gas sources (304)-(308), the system (300) can include any suitable number of gas sources. The gas sources (304)-(308) can be coupled to the reaction chamber (302) via the lines (314)-(318), which can each include flow controllers, valves, heaters, and the like. The exhaust (310) can include one or more vacuum pumps.

The controller (312) includes electronic circuitry and software to selectively operate valves, manifolds, heaters, pumps and other components included in the system (300). Such circuitry and components operate to introduce precursors, reactants, and purge gases from the respective sources (304)-(308). The controller (312) can control timing of gas pulse sequences, temperature of the substrate and/or reaction chamber, pressure within the reaction chamber, and various other operations to provide proper operation of the system (300). The controller (312) can include control software to electrically or pneumatically control valves to control flow of precursors, reactants and purge gases into and out of the reaction chamber (302). The controller (312) can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system (300) are possible, including different numbers and kinds of precursor and reactant sources and optionally further including purge gas sources. Further, it will be appreciated that there are many arrangements of valves, conduits, precursor sources, and purge gas sources that may be used to accomplish the goal of selectively feeding gases into the reaction chamber (302). Further, as a schematic representation of a system, many components have been omitted for simplicity of illustration, and such components may include, for example, various valves, manifolds, purifiers, heaters, containers, vents, and/or bypasses.

During operation of the system (300), substrates, such as semiconductor wafers (not illustrated), are transferred from, e.g., a substrate handling system to the reaction chamber (302). Once the substrate(s) are transferred to the reaction chamber (302), one or more gases from the gas sources (304)-(308), such as precursors, reactants, carrier gases, and/or purge gases, are introduced into the reaction chamber (302).

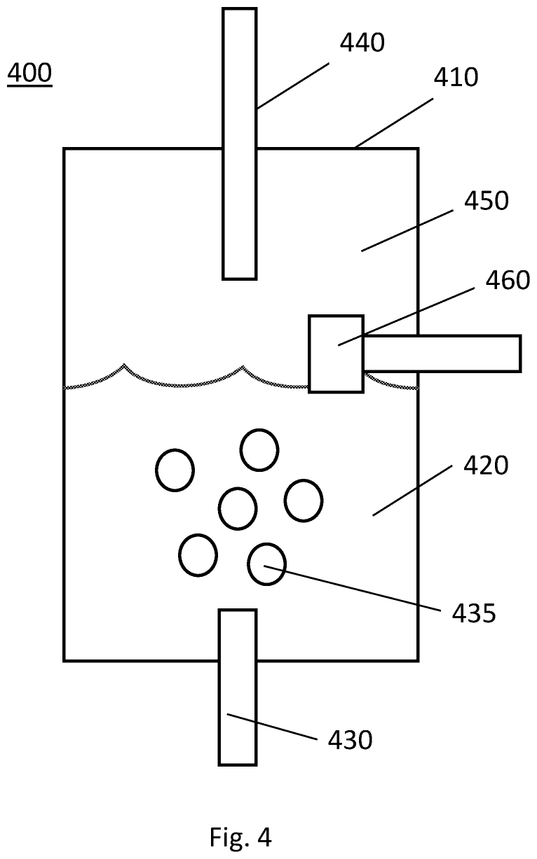

FIG. 4 shows an embodiment of a precursor vessel (400) that comprises a composition (420) as described herein. The composition (420) is protected from the outside atmosphere by a vessel wall (410). The composition (420) comprises a solvent and a precursor. The vessel (400) can be partially or wholly filled with the composition (420). In the embodiment of FIG. 4, the precursor vessel (400) is only partially filled with the composition (420) and the vessel (400) further comprises a head space (450) that comprises precursor vapor. Since the solvent has negligible vapor pressure, there is no, or at most a negligible amount of, solvent vapor in the head space (450). The precursor vessel (450) further comprises a carrier gas line (430) through which carrier gas can be provided to the vessel (400). In some embodiments, the carrier gas line (430) can be submerged in the composition (420). Thus, when carrier gas is provided via the carrier gas line (430), carrier gas bubbles are formed in the composition (420) and precursor can be efficiently entrained by the carrier gas. A float can be provided to measure the amount of composition (420) in the precursor vessel (400), which can provide an indication of the amount of precursor that is left in the precursor vessel (400). Carrier gas and precursor vapor can be removed from the precursor vessel (400) via a gas line (440). The gas line (440) can provide the resulting gas mixture to a reaction chamber where it can be used to form a layer.

The example embodiments of the disclosure described above do not limit the scope of the invention since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A composition comprising a precursor and a liquid solvent,
wherein the precursor undergoes at least one of self-condensation and polymerization in substantially pure form in an inert atmosphere at a temperature of at least 10° C. to at most 100° C.; and,
wherein the solvent has a vapor pressure of at most 1.0 mPa at a temperature of 20° C.

2. The composition according to claim 1 wherein the solvent comprises an ionic liquid.

3. The composition according to claim 2 wherein the ionic liquid comprises a cation selected from 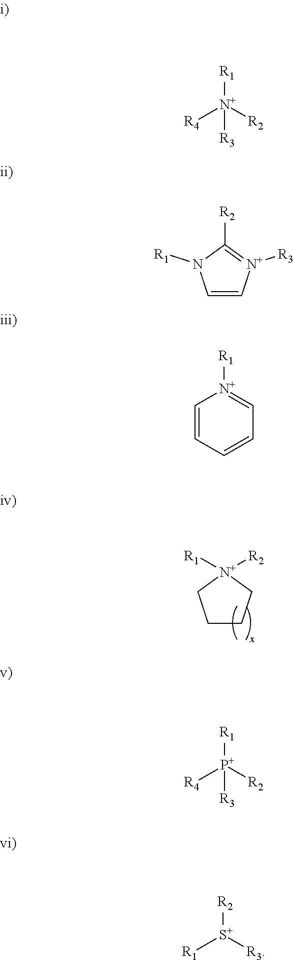
wherein x is 0 or 1, and wherein R1, R2, R3, and R4 are independently selected from a hydrocarbyl.

4. The composition according to claim 2 wherein the ionic liquid comprises an anion selected from CF₃CO₂⁻, N(CN)₂⁻, C(CN₃)₃⁻, SeCN⁻, CuCl₂, AlCl₄⁻, and ZnCl₄²⁻.

5. The composition according to claim 2 wherein the ionic liquid comprises an anion, the anion being selected from a boron-containing anion, a phosphorous-containing anion, and a sulphur-containing anion.

6. The composition according to claim 2 comprising a boron-containing anion, the boron-containing anion being selected from a list consisting of BF₄⁻, B(CN₄)⁻, CH₃BF₃⁻, CH₂CHBF₃⁻, CF₃BF₃⁻, C₂F₅BF₃⁻, n-C₃F₂BF₃⁻, and n-C₄F₉BF₃⁻.

7. The composition according to claim 2 comprising a phosphorous-containing anion, the phosphorous-containing anion being selected from PF₆⁻ and (C₂F₅)₃PF₃⁻.

8. The composition according to claim 2 comprising a sulphur-containing anion, the sulphur-containing anion being selected from a list consisting of CF₃SO₃⁻, N(SO₂CF₃)₂⁻, N(COCF₃)(SO₂CF₃)⁻, N(SO₂F)₂⁻, ROSO₃⁻, and SCN⁻, wherein R is a C1 to C20 hydrocarbyl.

9. The composition according to claim 2 wherein the ionic liquid has a formula according to formula a) 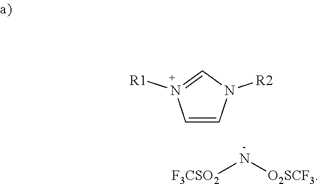
wherein R1 and R2 are hydrocarbyls.

10. The composition according to claim 9 wherein R1 and R2 are alkyls.

11. The composition according to claim 10 wherein R1 is methyl and R2 is ethyl.

12. The composition according to claim 1 wherein the solvent comprises a liquid polymer.

13. The composition according to claim 12 wherein the liquid polymer is a polyether.

14. The composition according to claim 1 wherein the precursor comprises one or more of a cyclic silane, a solid precursor, and a heterocyclic compound.

15. The composition according to claim 1 wherein the precursor comprises a heterocyclic compound, and wherein the heterocyclic compound comprises one or more bonds selected from a boron-nitrogen bond, a carbon-nitrogen bond, a silicon-carbon bond, and a nitrogen-silicon bond.

16. The composition according to claim 15 wherein the heterocyclic compound further comprises a silicon-silicon bond.

17. The composition according to claim 15 wherein the heterocyclic compound is borazine or a borazine derivative.

18. A method of storing a precursor in a precursor vessel, the method comprising
providing a precursor vessel comprising a composition according to claim 1; and,
maintaining the composition at a temperature of at least 10° C. to at most 50° C. for a duration of at least one week to at most one year.

19. A system comprising a reaction chamber, a substrate handling system, a precursor source, and a controller; wherein
the precursor source comprises a composition according to claim 1; and,
the controller is arranged for causing the system to provide a vapor to the reaction chamber, the vapor comprising the precursor comprised in the composition.

20. A precursor vessel comprising a container and a composition according to claim 1.
